(19) United States
(12) Patent Application Publication
(10) Pub. No.: US 2003/0184970 A1
(43) Pub. Date: Oct. 2, 2003

(54) Cooling arrangement and electrical apparatus with cooling arrangement

(76) Inventors: Volker Bosch, Stuttgart (DE); Bernd Wirnitzer, Leinfelden-Echterdingen (DE)

Correspondence Address: STRIKER, STRIKER & STENBY, 103 East Neck Road, Huntington, NY, 11743, US

(21) Appl. No.: 10/396,143

(22) Filed: Mar. 25, 2003

(30) Foreign Application Priority Data
Mar. 30, 2002 (DE) 102 14 363.2

(51) Int. Cl. H05K 7/20

(52) U.S. Cl. 361/688

(57) ABSTRACT

A cooling arrangement includes at least one support element (12), at least one electrical component mounted on the support element (12), and at least one cooling body (22, 24) mounted on the support element (12) for removing heat produced from the component (10). The support element (12) has at least one heat-conducting element (18), which thermally connects the component (10) with the cooling body (22, 24).

### BACKGROUND OF THE INVENTION

The present invention relates to a cooling arrangement for an electrical or electronic component.

It is known to use separate cooling bodies for cooling electronic components, whereby the component to be cool is mounted on the cooling body by means of an electrically isolated heat-conducting medium. The attachment of the component on the cooling body can take place, for example, by means of clamps or a screw.

With SMD-components (SMD—Surface Mounted Device), circuit boards made of copper-line aluminum are also used, on which the component to be cooled is directly soldered, whereby the circuit board, based on its good heat conductivity serves as a cooling body.

Furthermore, it is known to release the heat from the components to be cooled directly in the environment, without a cooling body, whereby the heat output takes place by means of convection and radiation. For improvement of the heat output, the soldering pads on the circuit board are enlarged to such a degree that their surfaces are sufficient for leading off the accumulated heat. In the event the soldering pads on the one side of the circuit board are not sufficient in this regard, then corresponding copper surfaces can be arranged also on the opposite side of the circuit board, whereby the thermal connection between the oppositely disposed soldering pads or copper surfaces takes place by means of common electrical through-contacts, or vias.

### SUMMARY OF THE INVENTION

The invention, in contrast, contemplates that a support element for an electrical component has a heat-conducting element, which leads the heat produced from the component to be cooled to a cooling body.

This indirect thermal connection between the components to be cooled and the cooling body offers the advantage of large constructive design leeway with the arrangement and shape of the cooling body and of the component to be cooled.

Preferably, the support element for the components to be cooled acts as a substantially common circuit board, whereby the circuit board can be designed for an assembly of discrete components or for SMD-components. It is also possible, however, that SMD-components as well as also discrete components are arranged on the circuit board.

In one variation of the invention, the component to be cooled and the cooling body are arranged on the same sides of the support element.

In a preferred embodiment of the invention, the component to be cooled and the cooling body, however, are arranged on different sides of the support element, so that the heat produced from the component to be cooled must be lead through the support element.

The heat-conducting element therefore preferably has a thermal through-connection, or via, made from a heat-conducting material, whereby it preferably acts as a common electrical via, which is used as an electrical connection between the opposite sides of a circuit board.

The term “a thermal through-connection or via”, as used in the frame of the present invention, includes all arrangements that are suited for leading heat from one side of the support element to the other side of the support element. In this regard, it is not necessary that the thermal through-connection or via is made also of an electrically conductive material.

The thermal through-connection or via therefore preferably has a bore or via hole through the support element, whereby the wall of the bore is coated with a heat-conducting material, such as, for example, copper.

For improving the thermal coupling, the through-connection or via opens to the upper surface of the circuit board, preferably in a flat or planar layer made of a heat-conducting material, whereby it preferably acts the same as the material comprising the conductors on the circuit board. Thus, for example, it is possible that the through-connection or via opens in a soldering pad, whereby the soldering pad, relative to a common soldering pad, can have a larger surface, in order to improve heat output.

Preferably, this heat-conducting layer is made of copper or a copper alloy, which preferably is passivated through soldering-stop lacquer or through a silver or tin layer.

In one variation of the invention, the bore penetrating through the support element is filled with a heat-conducting material, in order to enlarge the cross-sectional surface of the through-connection or via and therewith, to improve the heat conveyance. In this manner, it can operates as a solder, however, preferably a material with a minimal wetting affinity is used, thus, with the most even upper surface as possible exists.

According to one variation of the invention, the bore is filled with two different heating-conducting materials, whereby one material covers the inner wall of the bore, while the other material fills the remainder of the bore.

Preferably, the heat bridge between the opposite sides of the support element is formed by a plurality of common electrical through-connections or vias, whereby the individual through-connections or vias, respectively, are arranged in the region beneath the terminal contact (“footprint”) of the respective component and/or in the region of a copper surface around the respective terminal contact. In the frame of the present invention, then, preferably the number of through-connections or vias is increased over number of electrically required quantity, in order to guide the heat produced by the components to be cooled through the support element.

In a preferred embodiment of the invention, an electrically insulating heat-conducting medium is disposed between the support element and the cooling body. This offers the advantage that an electrical short circuit over the cooling body is prevented, so that the cooling body also can comprise an electrically conductive material. In addition, the heat-conducting medium makes possible a large-surface, thermal contacting of the cooling body as well as the compensation of upper surface unevenness, which, likewise, contributes to a reduction of the heat transfer resistance.

Preferably, the heat-conducting medium between the support element and the cooling body is in the form of a layer, in order to ensure the electrical isolation and the thermal contact over a large surface.

The cooling body used in the frame of the present invention can be common; however, preferably an apparatus housing or another type of component is used as a cooling body, so that, advantageously, a separate cooling body can be eliminated. Therefore, with a hand-held machining tool with an electric motor, the housing of the electric motor can be used as a cooling body, for example.

In addition, the present invention relates also to an electrical apparatus with a cooling arrangement, like the one described above. Therefore, preferably, the inventive cooling arrangement can be used in hand-held machining tools, accumulator worms, and grinding apparatus and the like, based on the large constructive design leeway, as well as the possibility of a particularly compact structure.

### BRIEF DESCRIPTION OF THE DRAWINGS

Further advantages are provided in the following description of the drawing. In the drawing, one embodiment of the invention is illustrated. The drawing, the description, and the claims contain a multitude of features in combination. The practitioner also is to recognize individual features and to combine them in further, practical combinations.

FIG. 1 shows a schematic representation of a cooling arrangement according to the present invention.

### DETAILED DESCRIPTION OF THE PREFERRED EMBODIMENTS

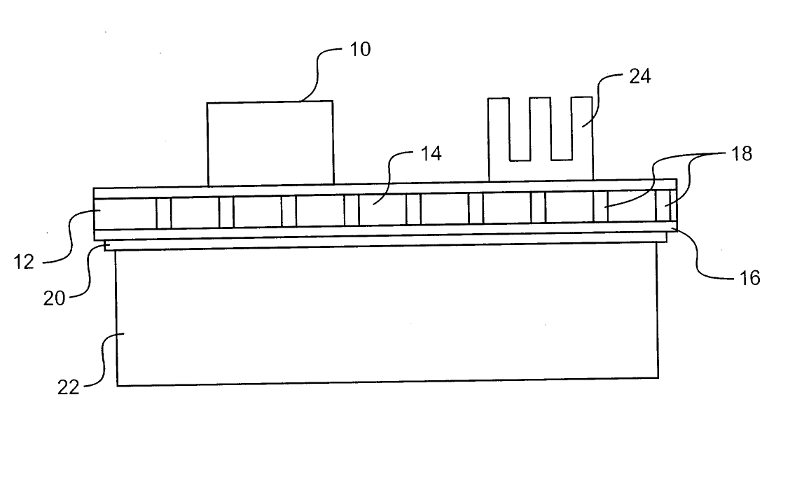

The embodiment represented in FIG. 1 shows the cooling arrangement of the present invention, which, for example, can be used for cooling of an electronic assembly.

The electronic assembly is represented only in an exemplary manner in the form of an individual electronic component 10, which is arranged on a circuit board 12. The component 10 to be cooled acts hereby as a so-called SMD component (SMD=Surface Mounted Device), which is directly attached to the circuit board; however, instead of or in addition to the SMD component, also discrete components can be arranged on the circuit board 12. Upon the mounting of discrete components on the circuit board 12, recesses for receiving the connecting wires must be provided on the underside of the circuit board 12, since the connecting wires project out to the underside of the circuit board 12.

For electrical contact of the components 12, a strip conductor layer 14 made of copper is mounted on the upper side of the circuit board 12 in the common manner, whereby the strip conductor layer 14 covers the upper surface of the circuit board 12 with copper only in the area of the individual strip conductors, while the upper surface of the circuit board 12 remains free. The component 10 is hereby in a common manner soldered with its terminal contacts onto the strip conductor layer 14.

On the underside of the circuit board 12, in contrast, a flat copper layer 16 is mounted, which extends in a large surface area over partial regions of the underside of the circuit board 12 and which makes possible a flat or planar heat output on the underside of the circuit board.

Further, the strip conductor layer 14 is thermally connected with the copper layer 16 by means of substantially common through-connections or vias 18, in order to transfer the heat produced from the component 10 through the circuit board 12 to the copper layer 16.

The through-connections or vias 18 comprise, respectively, a bore running at a right angle to the plane of the circuit board 12, the bore penetrating through the circuit board 12. The wall of this bore is coated with copper, whereby the copper coating forms a heat bridge between the upper side and the underside of the circuit board 12.

A layer 20 made of an electrically insulating, but heat-conducting, material is mounted on the underside of the copper layer 16. The layer 20, for example, can be lacquered or sprayed on. It is also possible, however, that the layer 20 forms a separate component, which is inserted upon assembly.

The copper layer 16 and the heat-conductive layer 20 provide for an equalizing of local temperature spikes, based on their good heat conductivity, so that the temperature in the copper layer 16 and in the heat-conducting layer 20 is substantially uniform. It is therefore advantageous that the heat removal is not limited to the spatially limited region under the respective component 10, rather extends over the entire surface of the copper layer 16 and the heat-conducting layer 20, whereby the heat transfer resistance is reduced and the cooling effect is improved.

Finally, the cooling arrangement has a cooling body 22, which is formed by a motor housing, so that a separate cooling body can be eliminated. The cooling body 22 is contacted in a planar or flat manner by the heating-conducting layer 20, so that the heat transfer resistance is relative minimal.

In operation of the cooling arrangement, the heat produced from the component 10 passes over the through-connections or vias 18 onto the copper layer 16, which relays the heat to the cooling body 22 via the layer 20.

In addition, the cooling arrangement has a blower, which for reasons of simplicity, is not illustrated here, and which actively cools the cooling body 22 by blowing the ambient air over the cooling body 22.

Finally, the illustrated cooling arrangement has a further cooling body 24, which is arranged on the same side of the circuit board 12 as the component 10.

It will be understood that each of the elements described above, or two or more together, may also find a useful application in other types of constructions differing from the types described above.

While the invention has been illustrated and described herein as a cooling arrangement and electrical apparatus with a cooling arrangement, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed as new and desired to be protected by Letters Patent is set forth in the appended claims.

1. Cooling arrangement with at least one support element (12), at least one component (10) mounted on the at least one support element (12) and at least one cooling body (22, 24) mounted on the at least one support element (12) for removing heat produced from the at least one component (10), characterized in that the at least one support element (12) has at least one heat-conducting element (18), wherein said at least one heat-conducting element thermally connects the at least one component (10) with the at least one cooling body (22, 24).

2. Cooling arrangement according to claim 1, characterized in that the at least one component (10) and the least one cooling body (24) are arranged on a same side of the at least one support element (12).

3. Cooling arrangement according to claim 1, characterized in that the at least one component (10) and the at least one cooling body (22) are arranged on opposite sides of the at least one support element (12).

4. Cooling arrangement according to claim 3, characterized in that the heat-conducting element (18) has at least one thermal via arranged in the at least one support element (12), wherein said at least one via is made from a heat-conducting material, in order to convey heat produced from the at least one component (10) on one side of the at least one support element (12) to the at least one cooling body (22) arranged on an opposite side of the at least one support element (12).

5. Cooling arrangement according to claim 4, characterized in that the at least one via (18) has a bore penetrating the at least one support element (12), wherein a wall of the bore is coated with a heat-conducting material.

6. Cooling arrangement according to claim 5, characterized in that the bore in the at least one support element (12) is filled with a heat-conducting material.

7. Cooling arrangement according to claim 6, characterized in that the bore in the at least one support element (12) is filled with a first heat-conducting material and a second heat-conducting material, wherein the first heat-conducting material covers an inner wall of the bore and the second heat-conducting material fills the remainder of the bore.

8. Cooling arrangement according to claim 4, characterized in that the at least one via (18) opens at least on one side of the at least one support element (12) into a flat layer (16) made of heat-conducting material.

9. Cooling arrangement according to claim 8, characterized in that the flat layer (16) made from a heat-conducting material is passivated by means of solder stop lacquer or a silver or tin layer.

10. Cooling arrangement according to claim 1, characterized in that an electrically insulating medium is arranged between the at least one cooling body (22) and the at least one support element (12).

11. Cooling arrangement according to claim 10, characterized in that the heating-conducting medium is formed as a layer.

12. Cooling arrangement according to claim 1, characterized in that the at least one cooling body (22) is a housing of an electric motor.

13. Electrical apparatus with a cooling arrangement as defined in claim 1.
